(19) United States
(12) Patent Application Publication
(10) Pub. No.: US 2015/0129017 A1
(43) Pub. Date: May 14, 2015

(54) THIN FILM SOLAR CELL LAMINATION STACK FOR HIGH VOLUME MANUFACTURING

(71) Applicant: Solexel, Inc., Milpitas, CA (US)

(72) Inventors: David Dutton, San Jose, CA (US); Pranav Anbalagan, Milpitas, CA (US); Karl-Josef Kramer, San Jose, CA (US); Mehrdad M. Moslehi, Los Altos, CA (US)

(21) Appl. No.: 14/326,461

(22) Filed: Jul. 8, 2014

Related U.S. Application Data
(60) Provisional application No. 61/843,849, filed on Jul. 8, 2013.

(51) Int. Cl. H01L 31/049; H01L 31/0216; H01L 31/0445

(52) U.S. Cl. CPC H01L 31/049; H01L 31/0445; H01L 31/0216
USPC 136/251; 438/66

(57) ABSTRACT

A lamination stack for etching solar cells is provided. At least two solar cell wafers are attached to corresponding backplane sheets which are larger than the solar cell wafers. Release layers larger than the solar cells and smaller than the backplane sheets are positioned on the backplane sheets on the opposite side of the attached solar cell wafers. The backplane sheets are bonded together along the exposed peripheral boundary formed by the release layers.

### CROSS-REFERENCE TO RELATED APPLICATIONS

This application claims the benefit of U.S. provisional patent application 61/843,849 filed on Jul. 8, 2013 which is hereby incorporated by reference in its entirety.

### FIELD OF THE INVENTION

This disclosure relates in general to the field of thin film semiconductor processing, and more particularly to lamination stacks for processing thin film solar cells.

### BACKGROUND

Current crystalline silicon (or other semiconductor absorber material) solar cell structures and processing methods often suffer from fabrication complexity and disadvantages relating to etching processes and cell bow and cell cracking/breakage during and/or after cell processing. For high volume manufacturing, solar cell fabrication often includes wet etchant processing (e.g., immersion bath etch, single sided horizontal etch, etc.) throughout the fabrication process which may result in unintended exposure and etching of the solar cell absorber itself or solar cell components. As a result, solar cell fabrication may be limited to certain alternative etching methods which reduce cell exposure to etchant but may also increase fabrication costs and/or decrease manufacturing through-put.

Additionally, solar cell fabrication may also induce significant stresses (e.g., thermal and/or mechanical stresses) on a semiconductor substrate which may lead to thermally-induced warpage and crack generation and propagation (by thermal cycling or mechanical stresses). Bowed or non-planar solar cell substrates pose significant challenges and possible manufacturing yield degradation during solar cell processing (such as during processing of crystalline silicon solar cells), and may present requirements for clamping down the solar cell substrate and/or the substrate edges onto a supporting substrate carrier to flatten the cell substrate during manufacturing process. Flattening solutions may complicate the solar cell manufacturing process, resulting in increased manufacturing cost and/or some manufacturing throughput and yield compromises. Bowed or non-planar solar cell substrates may further result in cell microcracks and/or breakage problems during module lamination and also subsequently during the PV module operation in the field (resulting in PV module power degradation or loss). These problems may be further aggravated in larger area solar cells, such as the commonly used 156 mm×156 mm format (square or pseudo square) solar cells.

Currently, crystalline silicon (both multi-crystalline and mono-crystalline silicon) has the largest market share in the photovoltaics (PV) industry. Moving to thinner crystalline silicon solar cells is understood to be one of the most potent and effective methods for PV cost reduction (because of the relatively high material cost of crystalline silicon wafers used in solar cells as a fraction of the total PV module cost). However, utilizing thinner crystalline wafers is hampered by the problem that thin wafers are extremely fragile, may suffer mechanical breakage during wafer handling and cell processing, and may cause resulting yield production yield losses. Further, using known designs and manufacturing technologies it is often difficult to balance the requirement of high mechanical yield and reduced wafer breakage rate with high manufacturing yields in PV factories in a cost effective manner.

Relating to substrate (semiconductor absorber) thickness, for current crystalline silicon wafer solar cells, moving even slightly thinner than the current thickness range of 140 μm to 200 μm starts to severely compromise mechanical yield during cell and module manufacturing. This is particularly challenging for larger cell sizes such as 156 mm×156 mm and 210 mm×210 mm cells (compared to smaller 125 mm×125 mm cells). Thus, manufacturable solutions directed to process very thin solar cell structures, such as with cell semiconductor absorbers thinner than about 100 μm down to micron-size-scale and submicron thickness, often must utilize a cell process during which the cell is fully supported by a either a temporary and/or a permanent host carrier throughout the process flow.

### SUMMARY

Therefore a need has arisen for lamination structures which provide etchant protection and structural backplane support for thin film solar cells. In accordance with the disclosed subject matter, backplane lamination stack structures and methods are provided which substantially eliminate or reduces disadvantage and problems associated with previously developed solar cell processing.

According to one aspect of the disclosed subject matter, a lamination stack for etching solar cells is provided. At least two solar cell wafers are attached to corresponding backplane sheets which are larger than the solar cell wafers. Release layers larger than the solar cells and smaller than the backplane sheets are positioned on the backplane sheets on the opposite side of the attached solar cell wafers. The backplane sheets are bonded together along the exposed peripheral boundary formed by the release layers.

Technical advantages of the disclosed subject matter include low processing temperatures, improved surface passivation, and increased optical properties for silicon substrates.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a high-level cross-sectional diagram of a known backplane laminated solar cell;

FIG. 2 is a cross-sectional diagram of a solar cell backplane lamination stack;

FIG. 3 is a cross-sectional diagram of a solar cell backplane lamination stack;

FIG. 4 is a cross-sectional diagram of a representative backplane lamination material system stack lay-up;

FIG. 5 is a high level process flow;

FIG. 6 is an alternative high level process flow using a backplane sheet having an embedded release layer; and

FIGS. 7A, 7B, and 7C are photographs outlining a scribe line scheme.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings.

Thin-film solar cell structures and fabrication process flows may utilize a permanent (and in some instances a temporary carrier) backplane which provides mechanical support, electrical interconnection, and other functionalities. Backplane supported back contact back junction structures may be particularly advantageous for low cost high efficiency solar cells using thin film absorbers. Further, the backplane lamination stacks provided herein may be used for etching silicon solar cells (e.g., monocrystalline or multicrystalline) or semiconductor materials such as compound materials (e.g., gallium arsenide).

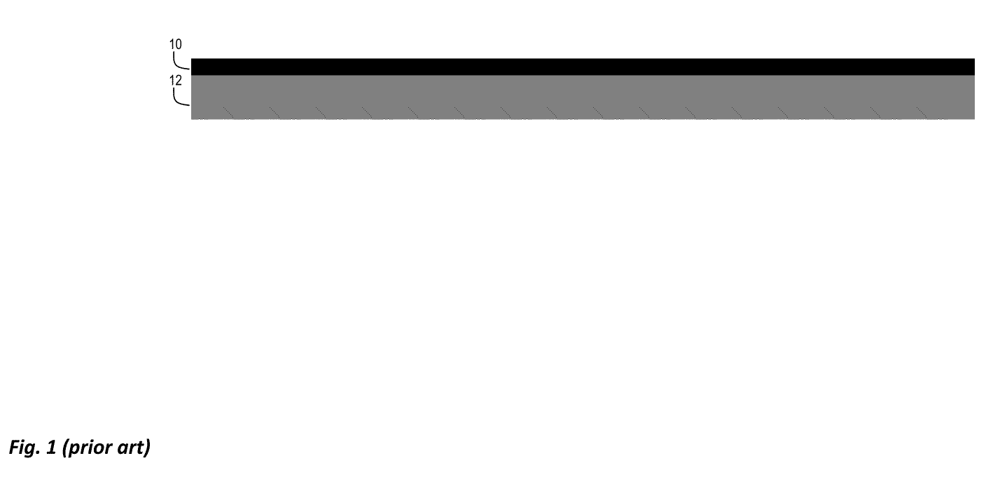

FIG. 1 is a high-level cross-sectional diagram of a known (prior art) backplane laminated solar cell. Backplane 12 (e.g., a 156×156 mm square laminate sheet) is laminated to the backside of solar cell 10 (e.g. a 156×156 mm square solar cell). As a general example for laminating crystalline silicon to a thin laminate film, FIG. 1 shows the resulting structure from the simple embodiment of a single silicon cell and single laminate sheet placed between the laminator plates. The single-layer lamination set up of FIG. 1 is asymmetric from front to back. As shown in FIG. 1, the resultant part (solar cell and laminate film as permanent backplane) has a matched area of laminate sheet to crystalline silicon (e.g., 156×156 mm) and a large surface area of exposed laminate sheet on the rear of the solar cell surface. In some embodiments, the laminate sheet may be larger than the solar cell although the cell to backplane interface is still exposed.

After fabrication, this structure may then be processed through additional cell fabrication including etch back, texture, passivation, and metallization processes. During these steps, the laminated cell may be treated as a single 156×156 mm cell during processing, e.g., through wet benches with traditional cassettes. Thus, handling of the wafers (e.g., in and out of a wet bench cassette) requires precise automation or human loading since the thin cell may be slightly flexible. This increased wafer handling sensitivity adds fabrication complexity and may nevertheless result in damaged wafers, wafer surfaces, and wafer edges contacted during wafer handling (i.e., the wafer surfaces in handling contacted). Additionally, during batch wet etch processes (or singled sided horizontal etch for example) the laminate on the rear of the cell of the structure of FIG. 1 is exposed to the same chemistry used to etch or clean the silicon surface. And while the laminate material may be chosen for compatibility with etch chemistries (e.g., etchants such as KOH, TMAH, nitric acid, HCl), processing errors and failure mechanisms may be particularly found within the marginality (i.e., the periphery) of the laminate where etchants may find and fill channels in the laminate and reach the laminate covered surface of the cell, causing delamination and corrosion at laminate and solar cell interface (e.g., backplane 12 and cell 10 in FIG. 1).

As a thin film support structure, a backplane may be laminated to a wafer at various points during solar cell processing (including both front and backside processing). In a particularly advantageous processing embodiment, back side processing in a back contact back junction solar cell structure (e.g., a combination of base and emitter region formation, backside passivation, on-cell metallization, etc.) may be performed prior to backplane lamination and certain frontside processing (e.g., a combination of saw damage removal, organic metal clean, front surface field formation, etch back, texture, passivation, anti-reflective coating, in some instances etch back wafer thinning, etc.) may be performed after backplane lamination. These and other frontside and backside post backplane lamination processes may utilize wet etch processes, such as immersion batch etch or single sided horizontal etch, during which the active backplane surfaces on the cell backside may be exposed to etchant. These backplane surfaces should be preserved (e.g. protected or otherwise resistant to the wet etching processing) and the solar cell and backplane interface protected to restrict etchant from entering into gaps in the solar cell and backplane interface.

The present application provides an innovative and elegant solution for the preservation of active backplane surfaces and the solar cell and backplane interface during wet etch processing. A symmetrical lamination stack having a center release sheet is utilized providing concurrent solar cell processing (e.g., solar cell sunnyside/frontside processing) for at least two solar cells. Among other advantages, the lamination stack disclosed herein: provides a symmetrical and stress balanced solar cell component during lamination and subsequent lamination steps which may mitigate cell bowing after processing; increases the rigidity of the backplane for subsequent process steps; decreases the laminate surface area and lamination parts interface (e.g., at solar cell and backplane) exposed to wet chemistry in wet etch steps; provides a handle at the cell perimeter for wafer handling and minimizing damage to the thin silicon perimeter; and increases through-put of parts at lamination and subsequent process steps. In other words, the disclosed solution provides effective backplane protection during wet etching (e.g. immersion bath etch) while increasing fabrication through-put (at least by a factor of two). Further, the resultant part (lamination structure) is symmetric from front to back thus minimizing stress and bow after lamination and subsequent process steps as material is taken away or added to the exposed solar cell surface (e.g., in solar cell fabrication processes such as wet etch/texture and passivation) thus decreasing processing failures and increasing manufacturing yield.

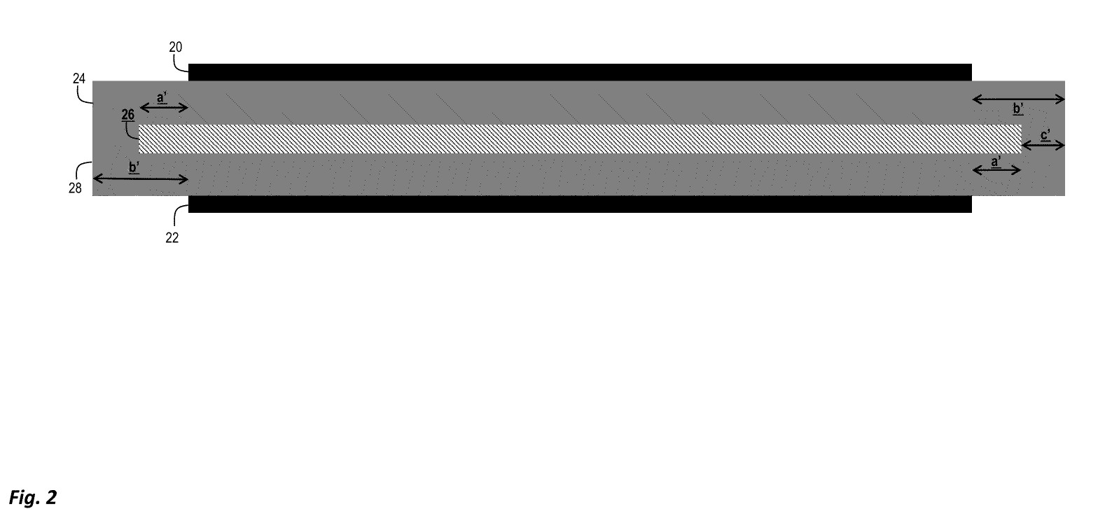

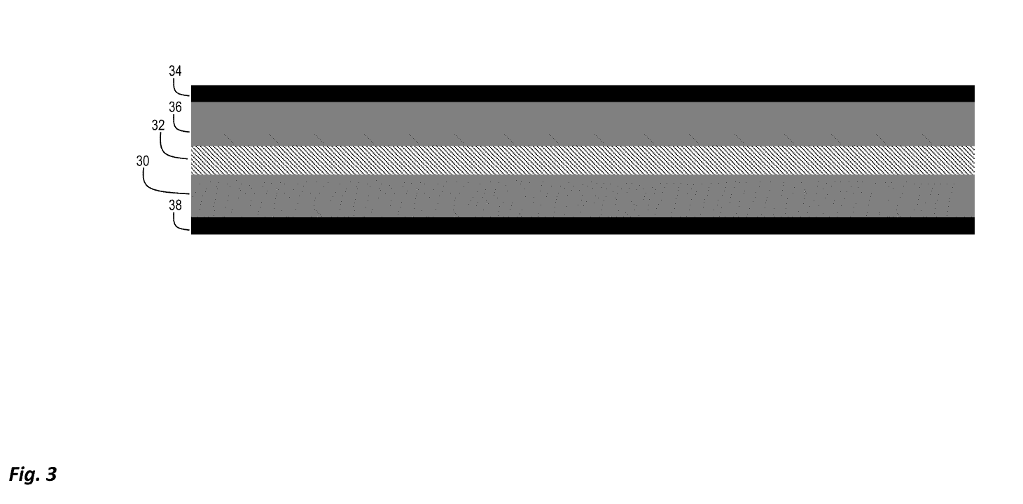

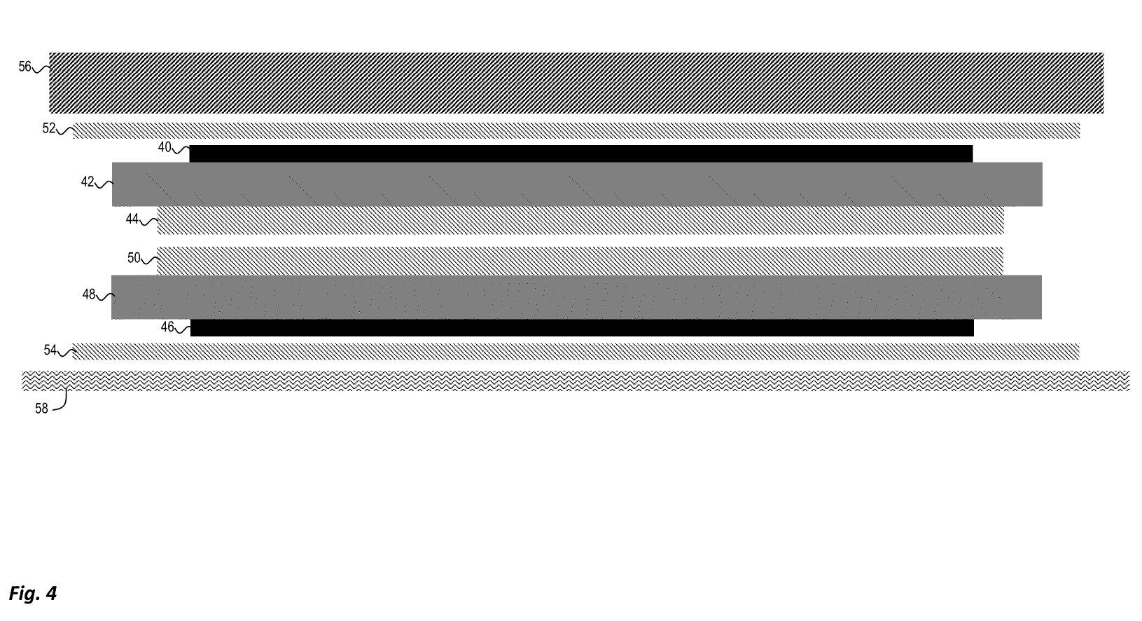

In the lamination stack provided herein, silicon cells are laminated to corresponding peripherally bonded backplanes separated by a release layer (or in another embodiment silicon cells are laminated to either side of a dual sided backplane having an embedded center release sheet). FIG. 2 is a cross-sectional diagram of a solar cell backplane lamination stack in accordance with the disclosed subject matter. Solar cell 20 and solar cell 22 are laminated to peripherally bonded backplanes 24 and 28 and separated by release sheet 26 (e.g., two release sheets each corresponding to a backplane sandwiched by the backplanes and compressed/sealed together during peripheral backplane bonding). Backplane laminate films 24 and 28 are larger than the solar cells 20 and 22 (shown as dimension b′ in FIG. 2). Embedded release sheet 26 is smaller than backplane laminate films 24 and 28 (shown as dimension c′ in FIG. 2) and larger than solar cells 20 and 22 (shown as dimension a′ in FIG. 2). This structure, a larger backplane and release sheet, also allows for perimeter/peripheral bonding of two laminate films beyond the release sheet (i.e., backplane peripherally bonded along dimension c′) and provides backplane surface and backplane/cell interface protection, effective backplane separation under the solar cell, and a handle during processing (i.e., the handle comprising bonded backplanes 24 and 28 and release sheet 26 along dimension b′). The cells may be released by manual cutting or laser ablation (for example a release layer may be selected transparent to IR wavelength and a backplane selected that is not transparent to IR) to the release sheet (i.e., a release/trim cut to release sheet 26 along dimension a′ in FIG. 2) to remove the bonded perimeter (shown as dimension c′ in FIG. 2) and expose the release sheet for part separation. In other words, a resulting structure after cutting or laser ablation to expose the release sheet (such as that shown in FIG. 3) and ready for part release along the release sheet. Release sheet 26 comprises two release sheets (e.g., a non-binding material) pressed together (see release sheet 50 and release sheet 44 in FIG. 4) by the peripheral backplane lamination bond along dimension c′ and are not otherwise attached. Thus, the center of the symmetric backplane lamination system is the release sheet and the outer layer is the silicon solar cell and only the perimeter “handle” area of the backplanes are exposed (i.e., the backside of the laminate film backplane and the cell/backplane interface is protected) to wet chemistry which may be removed as scrap at a later stage of the integration process.

In one embodiment, the backplanes (e.g, each having a corresponding attached release sheet) of backplane laminated solar cells are peripherally laminated together and separated by the compressed release sheets. In another embodiment, the solar cells are laminated to a dual-sided backplane sheet having an embedded release layer. FIG. 3 is a cross-sectional diagram of a solar cell backplane lamination stack after a release or trim cut to the release layer (e.g., the release cut positioned along dimension a′ in FIG. 2). Solar cell 34 is laminated to backplane 36 which is attached to backplane 30 and solar cell 38. Backplane 36 and backplane 30 are separated by release sheet 32 (e.g., comprising two compressed release sheets each corresponding to a backplane). As shown, the cells are non-bound and may be pulled apart along the compressed release sheet interface (see release sheet 50 and release sheet 44 in FIG. 4).

Wet etch processing may include a silicon etch back (e.g, KOH) used to thin a wafer thickness, for example from 200 μm to 60 μm in a wet bath immersion etch during which the lamination stack disclosed provides backplane protection from the wet etchant as well as mechanical wafer support. In other words, after a thinning etch and subsequent cell release along the release layer, the resulting active backplane surface and backplane/cell interface is free from etchant damage caused by etchant exposure. Further, as the lamination structures provided increase the rigidity of the cell and backplane (i.e., decrease the flexibility of the cells) allowing for placement of more cells in a cassette (e.g., in an etch cassette for a wet bench) during an etchant process (i.e., in some instances cells flexing requires empty buffer cassette slots between used cassette slots)—thus further improving through-put beyond concurrent cell processing with two cells per cassette slot by allowing for the use of more slots (i.e., there is less need for buffer cassette slots as the structure has increased rigidity).

After etch processing, additional solar cell fabrication processing such as cell shape definition cuts, texturization, and passivation may be performed while the cells protected by the lamination stack or after the cells are separated along the release layer. Further, this backplane lamination system may be packaged as a flat product having outer solar cell layers and inner backplane lamination films and a center release sheet.

FIG. 4 is a cross-sectional diagram of a representative backplane lamination material system stack lay-up for lamination in one step in accordance with the disclosed subject matter. Silicon solar cell 40 is laminated to backplane sheet 42 which is attached to release sheet 44. The backplane may be any supporting material for example a polymeric material such as prepreg. The release sheet may be a non-stick polymer or fluoropolymer such as PTFE. Silicon solar cell 46 is laminated to prepreg sheet 48 which is attached to release sheet 50 (e.g., PTFE). And while the center release sheet is shown as two sheets of a consumable film (e.g., PTFE), the center sheet may also be a re-usable material. Pads 52 and 54 (e.g., PTFE) and pad 56 (e.g., a lamination assist pad) and pad 58 (e.g. a lamination assist pad) may be used to apply pressure during the lamination process.

Consumable release sheet materials include a spray-on release coating deposited on the backside of the backplane (i.e., the backplane surface opposite the solar cell absorber) prior to lamination. The release spray may use a physical hard mask to prevent coating of the perimeter handle bonded backplane (e.g., prepreg to prepreg interface), which may should not coated to ensure the perimeter is sealed. Example spray release agents include PTFE based sprays, silicone, and nano-particle based sprays. A spray-on release coating may further reduce cost of lamination materials and the number of parts required during lamination alignment.

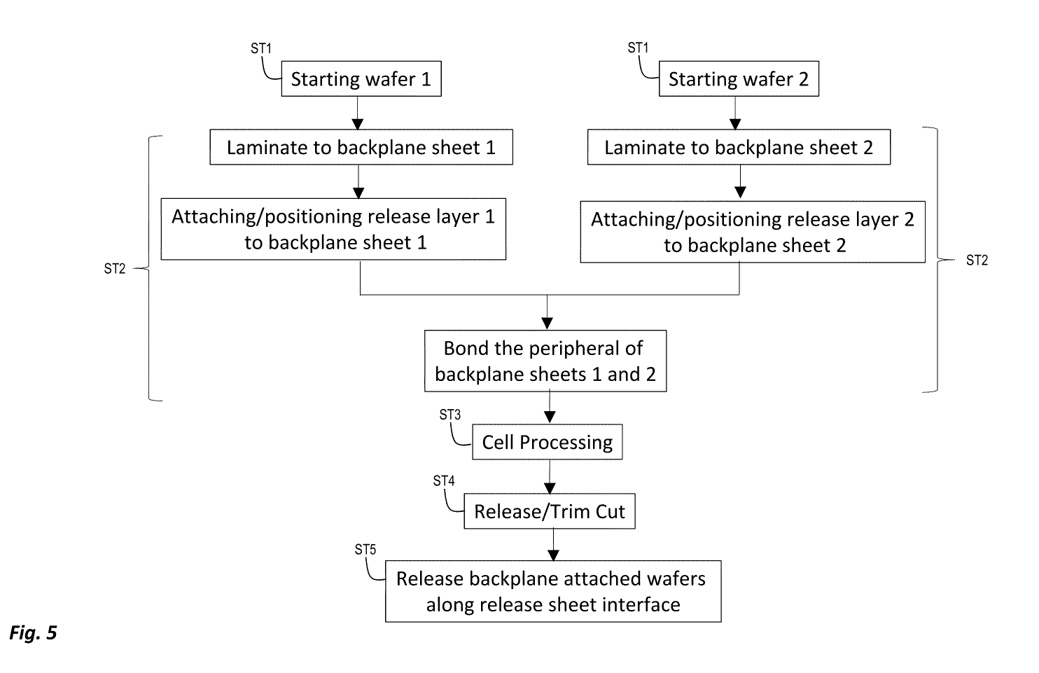

The lamination stack provided herein may be used for and incorporated in high-volume solar cell fabrication processes. For example, FIG. 5 is a high level process flow in accordance with the disclosed subject matter. Two starting wafers (ST1 in FIG. 5) are laminated to corresponding backplane sheets attached to corresponding release layers and peripherally bonded at the backplane to backplane interface (dimension c′ in FIG. 2) in one step (ST2 in FIG. 5). Alternatively, each backplane may be pre-attached to a release layer prior to cell lamination. After the lamination structure is formed, cell processing on the exposed cell surface may begin (ST3 in FIG. 5)—for example wet etch back thinning of a silicon wafer, frontside texturization, etc. After which a release/trim cut is made to the release layer (ST4 in FIG. 5), the lamination stack handle is discarded (e.g. handle comprising the lamination stack along dimension b′ in FIG. 2), and the backplane attached solar cells may be release along release layer 1 and release layer 2 interface (ST5 in FIG. 5).

After the release/trim cut is complete, the two parts may remain connected by Van der Wall's forces. A slight amount of force may be required to separate the release sheets, for example supplied by using a 156 mm square wafer (200 um thick) slid gently between the two parts (a process which may be automated).

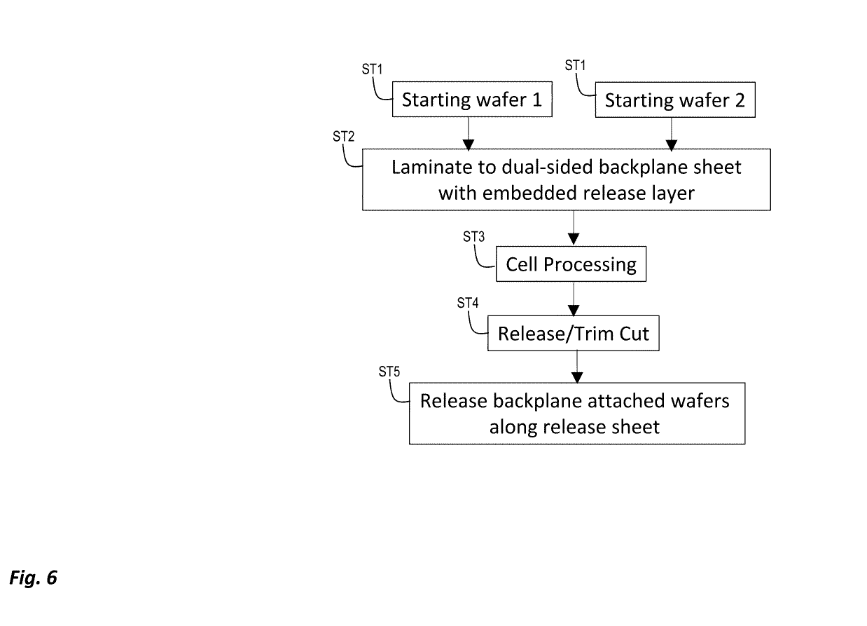

FIG. 6 is an alternative high level process flow using a backplane sheet having an embedded release layer. Two starting wafers (ST1 in FIG. 6) are laminated to a dual-sided backplane sheet having an embedded release layer (ST2 in FIG. 6). Cell processing on the exposed cell surface may then begin (ST3 in FIG. 6). After which a release/trim cut is made to the release layer (ST4 in FIG. 6), the lamination stack handle is discarded (e.g. handle comprising the lamination stack along dimension b′ in FIG. 2), and the backplane attached solar cells may be released along the release layer (ST5 in FIG. 6.

The solar cells are released along the release layer (e.g., Pacolone) for example using an etchant selective to the release layer (i.e., a release sheet temperature or light sensitive or reactive to some form of gas based or liquid chemistry), a mechanical pull or cutting process, or a combination.

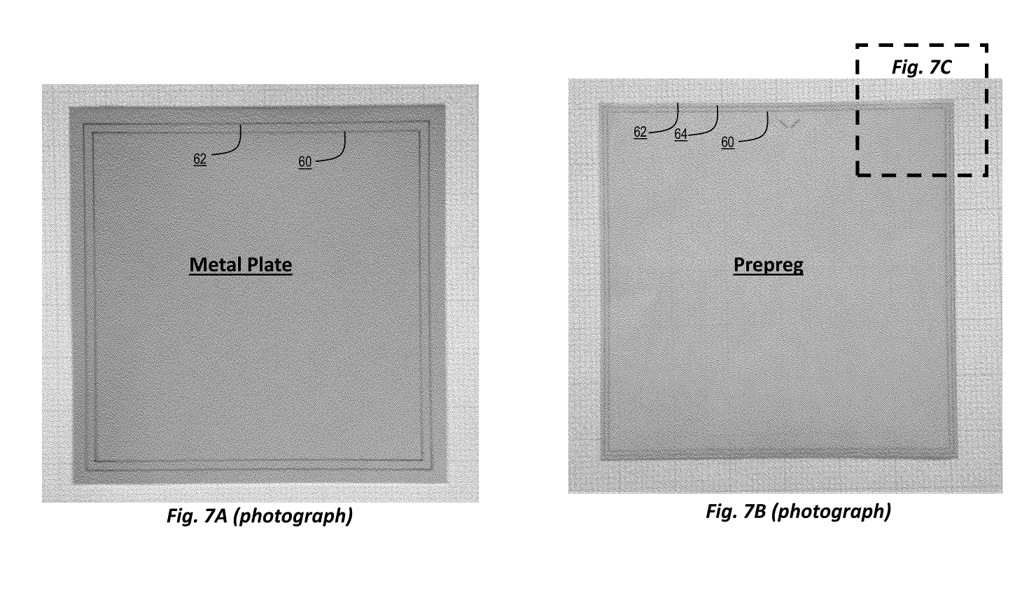

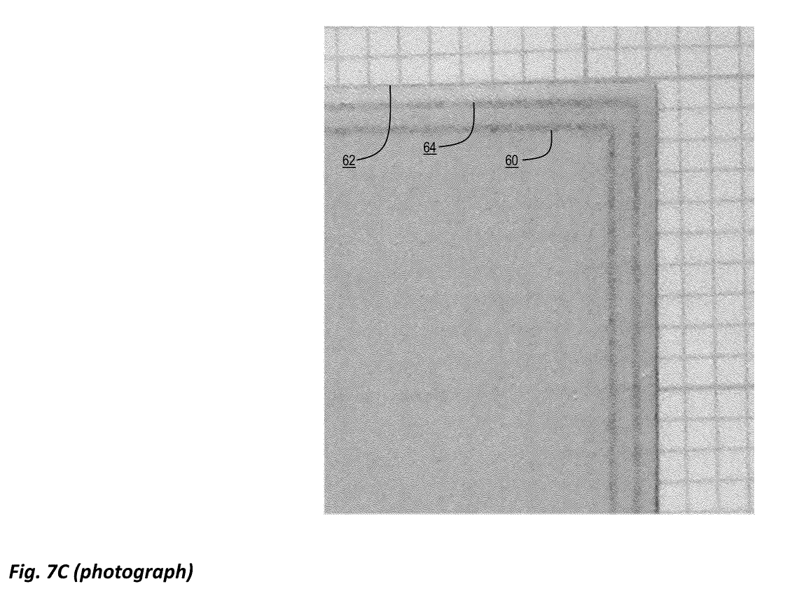

During cell processing, alignment of the cell to the backplane (e.g., prepreg) is critical. Scribe lines may be used as fiducials during backplane lamination. FIGS. 7A, 7B, and 7C are photographs outlining a scribe line scheme for alignment and cutting (if needed) of the backplane film and release sheet. FIG. 7A shows metal plate for forming scribe line fiducials on a backplane (e.g. prepreg) attached to a solar cell. Scribe line 60 is a cell guide (e.g., 156×156 mm) and scribe line 62 is backplane (e.g. prepreg) guide and cut line (e.g., 165×165 mm). FIG. 7B shows the underlying cut prepreg and release layer scribe line 64 (e.g., 160×160 mm). FIG. 7C is an expanded view of a portion of FIG. 7B.

The release (trim) cuts to expose the release layer and remove the laminate handle may be performed using mechanical scribing (cutting with a knife) or laser (e.g., IR pulsed nanosecond laser) down to sub millimeter accuracy. For example, with reference to the dimensions of FIG. 7, a 158×158 mm release cut leaves approximately a 1 mm boarder of prepreg material around the cell. If a reusable release sheet is used, a release cute using laser which transmits through the release sheet can be used to cut through the laminate film, expose the release sheet, and remove the laminate handle. For example, a pulsed nanosecond IR laser may be used in the case of a prepreg backplane and a PTFE release layer—thus allowing for PTFE release layer reuse.

The backplane material may be made of a thin (for instance, with a thickness in the range of about 50 microns to about 250 microns thick), flexible, and electrically insulating polymeric material sheet such as an inexpensive aramid fiber prepreg material, such as those commonly used in printed circuit boards, which meets cell process integration and reliability requirements including coefficient of thermal expansion (CTE) matching with the solar cell absorber (e.g., crystalline silicon, mono or multi crystalline, for crystalline silicon solar cells). And while various suitable polymeric (such as plastics, fluropolymers, prepregs, etc.) and suitable non-polymeric materials (such as glass, ceramics, etc.) may be used as the electrically insulating backplane material, the desired backplane material choice depends on many considerations including, but not limited to, cost, ease of process integration, relative CTE match to silicon, thermal stability, chemical resistance, reliability, flexibility/pliability, etc.

Prepreg sheets are used as building blocks of printed circuit boards and may be made from combinations of resins and CTE-reducing fibers or particles. Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Further, backplane resin content may be adjusted to mitigate cell bow after processing (for example a general trend of higher backplane resin content leading to higher cell bow has been observed). Covered by a flexible backing paper, prepregs may be easily handled and remain flexible/pliable for a certain time period (out-life) at room temperature. The backplane material may be a relatively inexpensive, low-CTE (typically with CTE <10 ppm/° C., or in some instances with CTE <5 ppm/° C.), thin (usually 50 microns to 250 microns, and in some instances in the range of about 50 to 150 microns) prepreg sheet which is relatively chemically resistant to the optional silicon thinning etch chemistry (e.g., alkaline or acidic silicon etch chemistry) and texturization chemicals (e.g., alkaline or acidic silicon texturization chemistry), and is relatively thermally stable at temperatures up to at least 180° C. (and in some instances to temperatures as high about 400° C. during the back-end solar cell processing).

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for manufacturing a thin film solar cell, comprising:
laminating at least two solar cell wafers to at least two corresponding backplane sheets, said backplane sheets larger than said solar cell wafers and attached to a release layer on the opposite side of said solar cell wafers; said lamination bonding the periphery of said backplane sheets of said backplane attached solar cells;
etching said solar cell wafers, said etching thinning said solar cell wafers;
cutting through said backplane sheets to expose said release layer; and
separating said backplane attached solar cells along said release layer interface.

2. The method of claim 1, wherein said backplane sheet is a prepreg sheet.

3. The method of claim 1, wherein said cutting through said backplane sheet is a mechanical process.

4. The method of claim 1, wherein said cutting through said backplane sheet is a laser process.

5. The method of claim 1, wherein said etching is performed in an immersion bath.

6. The method of claim 1, wherein said etching is single sided horizontal etch.

7. A thin film solar cell lamination stack, comprising:
at least two solar cell wafers attached to at least two corresponding backplane sheets, said backplane sheets larger than said solar cell wafers;
release layers positioned on backplane on the opposite side of said solar cell wafers;
said release layers larger than said solar cells and smaller than said backplane sheets, wherein said release layers form an exposed peripheral boundary of said backplane sheets; and
wherein said backplane sheets are bonded together along said exposed peripheral boundary.

8. The thin film solar cell lamination stack of claim 7, wherein said backplane sheet is a polymer.

9. The thin film solar cell lamination stack of claim 7, wherein said backplane sheet is prepreg.

10. The thin film solar cell lamination stack of claim 7, wherein said release layer is a non-stick polymer.

11. The thin film solar cell lamination stack of claim 7, wherein said release layer is a non-stick fluoropolymer.

12. The thin film solar cell lamination stack of claim 7, wherein said release layer is a spray on coating.

13. The thin film solar cell lamination stack of claim 7, wherein said release layer is a spray on PTFE based spray.
